(19) United States
(12) Patent Application Publication
(10) Pub. No.: US 2009/0321955 A1
(43) Pub. Date: Dec. 31, 2009

(54) Securing integrated circuit dice to substrates

(76) Inventors: Sabina Houle, Phoenix, AZ (US); Johanna Swan, Scottsdale, AZ (US); Kevin George, Chandler, AZ (US)

Correspondence Address: TROP, PRUNER & HU, P.C., 1616 S. VOSS RD., SUITE 750, HOUSTON, TX, 77057-2631, US

(21) Appl. No.: 12/215,860

(22) Filed: Jun. 30, 2008

(51) Int. Cl. H01L 23/488; H01L 21/60

(52) U.S. Cl. 257/777; 438/109; 257/E23.023; 257/E21.511

(57) ABSTRACT

A conductive material may be jet dispensed (i.e. jet sprayed) on an integrated circuit die and a bond pad to form a conformal electrical connection on and between the bond pad and the die. In some cases, a smaller package footprint and/or height may result.

### BACKGROUND

This relates generally to securing integrated circuits in the form of dice to substrates such as packages, printed circuits, or other surfaces.

Conventionally, a die is secured to a package by wire bonding. The wire bonds are done by automated equipment that finds pads on the package and on the substrate and connects them via wires that are soldered into position on the pads and cut to length.

Because of the phenomenon called “wire bond sweep,” there is a certain footprint or size associated with the wire bonding process. Generally, the distance from a pad on the die to a pad on the substrate must be about 25 micrometers and is often 50 to 60 micrometers due to package design.

As a result, the ability to reduce the size of the package is, to some degree, limited by the wire sweep. Also, because the wires bend upwardly going from the die to the package, there is also a certain necessary package height.

### BRIEF DESCRIPTION OF THE DRAWINGS

FIG. 1 is a side elevational view of one embodiment of the present invention at an early stage of manufacture;

FIG. 2 is a side elevational view of the embodiment shown in FIG. 1 at a subsequent stage in accordance with one embodiment;

FIG. 3 is a side elevational view of the embodiment shown in FIG. 2 at a subsequent stage in accordance with one embodiment;

FIG. 4 is a top plan view of the attached die in accordance with one embodiment of the present invention;

FIG. 5 is a side elevational view of another embodiment at an early stage of manufacture;

FIG. 6 is a side elevational view at a subsequent stage in accordance with one embodiment; and

FIG. 7 is a side elevational view at a subsequent stage of one embodiment.

### DETAILED DESCRIPTION

In accordance with some embodiments of the present invention, wire bonds that secure dice to integrated circuit substrates, such as packages or printed circuit boards, can be replaced. Instead, material may be deposited directly on the integrated circuit dice (or layers over the integrated circuit dice). As a result of the elimination of wire bond technologies, in some cases, the spacing between the bond pads on the dice and the bond pads on the substrate may be reduced. This may result, for example, in reduced package sizes. In addition, the package height may be reduced because of the elimination of upwardly arching wire bonds.

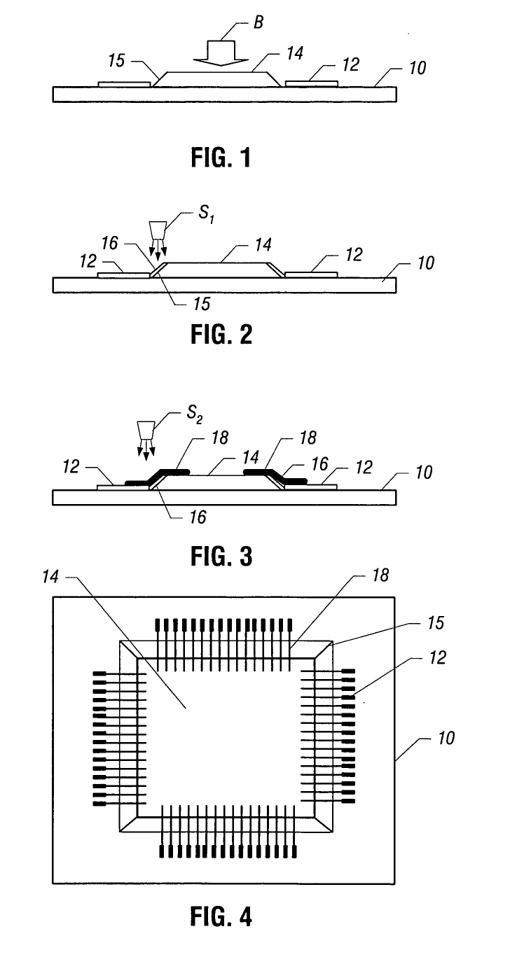

Referring to FIG. 1, in accordance with one embodiment, a die 14 may be formed with chamfered or angled edges 15. In one embodiment, the angled edges 15 may be formed by cutting the edges at an angle when the dice are separated from the wafer. For example, a laser milling machine may be operated at an angle to form the chamfered edges 15.

The die 14 may be temporarily attached to a substrate 10. The substrate 10 may be part of the package, part of a printed circuit board, or any other component to which it is desirable to attach a die. The substrate 10 may include bond pads 12. In some embodiments, the bond pads 12 may be situated very close to the integrated circuit die 14 because, without wire bonding, there is no need to account for wire sweep.

As a result, a more compact component may be fabricated. Thus, initially, the die 14 is simply positioned on the substrate 10 in the direction indicated by the arrow B, closely adjacent an array of bond pads 12.

While an embodiment is shown with chamfered edges, the edges 15 may also be formed by depositing a material along the edges of a conventional rectangular die or by providing an insert of the appropriate shape between the die 14 and the bond pads 12.

In some embodiments, a material 16 may be deposited on the chamfered edges 15 using a jet dispense tool S₁, as shown in FIG. 2. The material 16 may be an insulator in one embodiment, and may function to match the coefficient of thermal expansion of the die 14. This may reduce or eliminate cracking of the die.

In one embodiment, the material 16 may be a polymer and may include silicon. For example, a benzocyclobutene (BCB)-silicon copolymer or other silicon-based coatings may be utilized. As another example, a thermoset polymer may be utilized. A rigid urethane, epoxy, or reactive thermoplastic elastomer (TPE) may also be used in some cases. The polymer may be partially reacted thermoset with reactive end groups, such as double carbon bonds and/or hydroxide groups, which react and crosslink with the polymer chains of the materials that will be deposited on top of them. In many cases, the material 16 has a coefficient of thermal expansion that very closely matches the coefficient of thermal expansion of the die 14.

Next, as shown in FIG. 3, a solder material 18 may be deposited so as to bridge from bond pads (not shown) on the top of the die 14 to the bond pads 12 on the substrate 10. In one embodiment, the solder, jet dispensed by the jet dispense tool S₂, is a colloidal solution of tin with nano-sized particles of tin coated with polymer chains to protect them against oxidation. As used herein, “jet dispensing” is forming a spray of discrete conductive particles at flow rates higher than 50 milligrams per second. Jetting involves producing a stream of discrete volumes at frequencies greater than 100 Hz.

The tool S₂ is a solder jet tool that ejects nano-sized particles at relatively high velocity. One such tool is the DispenseJet® DJ-9000 high speed jet dispensing tool, available from Asymtek of Carlsbad, Calif. 92008.

The length of the line and its thickness is controlled by the rate of movement of the tool S₂ along the coated surface. Of course, an array of tools S₂ may simultaneously form a larger number of lines. Alternatively, the die substrate 10 may be moved relative to the tool S₂.

The nano-sized particles coalesce to form lines through a series of individual spots that are dispensed in an overlapping method. Each line may be on the order of 10 to 20 microns in width in some embodiments. As a result, in some cases, 10 micron line spacing may be achieved. The lines conform to the underlying structures, such as the bond pad 12, substrate 10, edge 15, and the top of die 14.

In some embodiments, an integrated circuit package including the die 14 and substrate 10 has a smaller size, both horizontally in the plane of the die and vertically or perpendicularly to the plane of the die 14, compared to wire bonded packages.

Referring to FIG. 4, the jet dispensed line 18 extends from bond pads 12 on the upper surface of the substrate 10, up the inclined chamfered edge 15 of the die 14, and on to a corresponding bond pad (not shown) on the top of the die 14. Since the line 18 conforms to the shape of the die 14, it forms a very low profile structure.

Because little or no bond pad-to-die spacing is needed for applying the line 18, a smaller overall structure footprint may be achieved.

Other solders that may also be jet dispensed include silver or copper solders. The solders may include flux, such as formic acid, or may be fluxless solders.

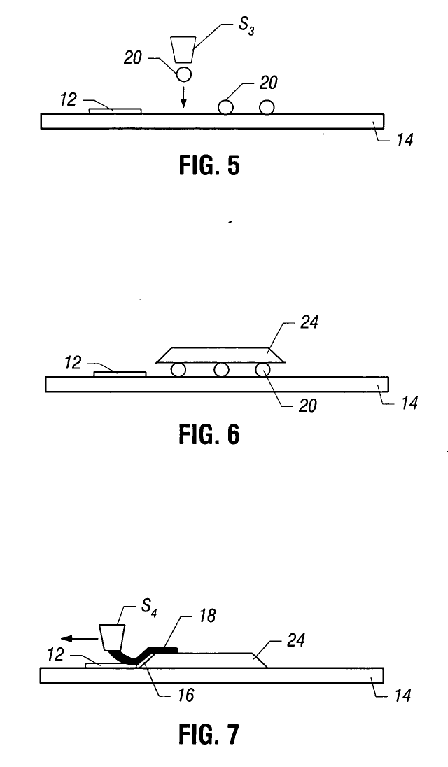

Referring to FIG. 5, in accordance with another embodiment, a jet dispense tool S₃ may provide pulses or globules 20 or solder on a substrate 14 near a bond pad 12. The globules 20 may be larger than nano-size and may correspond to the size of desired solder balls. As a result, solder balls may be dispensed by a tool S₃ that moves over the surface of the substrate 14 and applies solder balls in a two-dimensional array. After applying the solder balls, as shown in FIG. 5, a die 24 may be positioned over the solder globules 20, as shown in FIG. 6. For example, the solder globules 20 may be allowed to harden so that, at a later time, the die 24 with chamfered edges may be applied. Then, the die 24 may be heated, for example, in a belt furnace, causing the solder globules 20 to secure the die 24 to the substrate 14, as shown in FIG. 7.

Next, the insulator 16 may be applied, as previously described. Then, a jet dispense tool S₄ may be moved in the direction indicated by the arrow to apply a conductive paste bead 18 to connect bond pads (not shown) on the top of the die 24 to the bond pad 12. In some embodiments, the tool S₄ may apply nano-sized particles to coalesce to form a line of conductive solder material. In other embodiments, the tool S₄ may simply dispense a continuous paste which forms a layer, as positioned underneath the moving tool S₄.

As a result, a conforming, low height connection may be achieved that is amenable to compact processing. Compactness is achieved because there is no need to account for a wire sweep in the spacing between the die and the associated bond pads.

In one embodiment, the substrate 10, shown in FIGS. 5 to 7, may be another integrated circuit die. In such case, a stacked structure may be formed. In some cases, the conductive line may conform to either or both dice.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
jet dispensing a solder to form an electrical connection between a bond pad on a surface and a bond pad on an integrated circuit.

2. The method of claim 1 including moving a jet dispense tool to jet dispense a conductive line on the integrated circuit.

3. The method of claim 2 including forming a chamfered surface on the edge of said integrated circuit and applying said conductive line to said chamfered surface.

4. The method of claim 3 including forming said conductive line by jet dispensing solder.

5. The method of claim 4 including applying an insulator over said chamfered edge.

6. The method of claim 5 including applying an insulator having a coefficient or thermal expansion that closely matches the coefficient or thermal expansion of said integrated circuit.

7. The method of claim 1 including forming a conformal coating on said integrated circuit and said surface to electrically bridge said bond pads.

8. The method of claim 1 including jet dispensing solder balls.

9. The method of claim 1 including forming a stacked package comprising at least two stacked dice, and forming a conductive line by jet dispensing a conductive material on at least one of said dice.

10. The method of claim 1 wherein jet dispensing includes spraying a plurality of nano-sized particles that overlap to form a conductive line.

11-20. (canceled)
